(19) United States
(12) Patent Application Publication
(10) Pub. No.: US 2024/0258190 A1
(43) Pub. Date: Aug. 1, 2024

(54) FLOATING HEAT SPREADER WITH GUIDED MECHANISM

(71) Applicant: Advanced Micro Devices, Inc., Santa Clara, CA (US)

(72) Inventors: Gamal REFAI-AHMED, Santa Clara, CA (US); Chi-Yi CHAO, New Taipei City (TW); Christopher JAGGERS, Austin, TX (US); Suresh RAMALINGAM, Fremont, CA (US); Sukesh SHENOY, Austin, TX (US)

(21) Appl. No.: 18/102,065

(22) Filed: Jan. 26, 2023

(51) Int. Cl. H01L 23/367; H01L 21/48; H01L 23/00; H01L 23/40; H01L 23/427

(52) U.S. Cl. CPC H01L 23/3675; H01L 21/4817; H01L 23/4006; H01L 23/427; H01L 24/29; H01L 24/32; H01L 2023/4068; H01L 2023/4087; H01L 24/16; H01L 24/33; H01L 24/73; H01L 25/0655; H01L 2224/16225; H01L 2224/2919; H01L 2224/2929; H01L 2224/293; H01L 2224/29387; H01L 2224/32225; H01L 2224/32245; H01L 2224/33181; H01L 2224/73204; H01L 2224/73253; H01L 2924/0665

(57) ABSTRACT

A chip package includes a substrate and an integrated circuit (“IC”) die mounted to the substrate. A stiffener frame is mounted to the substrate and circumscribes the IC die. The stiffener frame has a plurality of connected walls that define an opening in the stiffener frame. The chip package also includes a lid having a bottom side facing a top surface of the IC die. The lid has at least a first guide and a second guide extending from the bottom side of the lid. The first guide can be disposed outward or inward of the stiffener frame. The first guide has a side facing an outer wall surface or an inner wall surface of the stiffener frame. The first guide and the second guide are positioned to limit movement of the lid relative to the stiffener frame in two directions.

### TECHNICAL FIELD

Examples of the present disclosure generally relate to integrated circuit packaging and, more particularly, to integrated circuit packaging using a floating heat spreader with guided mechanism.

### BACKGROUND

Electronic devices (e.g., computers, laptops, tablets, copiers, digital cameras, smart phones, and the like) often employ integrated circuits (ICs, also known as “chips”). These integrated circuits are typically implemented as semiconductor dies packaged in integrated circuit packages. The semiconductor dies may include memory, logic, and/or any of various other suitable circuit types.

Many integrated circuits and other semiconductor devices utilize an arrangement of bumps, such as a ball grid array (BGA) or a flip chip ball grid array (FCBGA), for surface mounting packages to a circuit board (e.g., printed circuit board (PCB). Any of various suitable package pin structures, such as controlled collapse chip connection (C4) bumps or microbumps (as used in stacked silicon interconnect (SSI) applications), may be used to conduct electrical signals between a channel on an integrated circuit (IC) die (or other package device) and the circuit board on which the package is mounted.

As the density of active components in IC dies continues to rise, the IC dies produce an ever-increasing amount of heat during operation. This heat is typically thermally conducted from the IC dies through a thermal interface material (TIM) to a lid and then to a heat sink to facilitate heat dissipation away from the IC dies. Heat spreaders (e.g., vapor chambers) may be used to spread heat from a concentrated heat source such as an IC die to a larger heat sink.

### SUMMARY

One example of the present disclosure is a chip package. The chip package generally includes a substrate and an integrated circuit (“IC”) die mounted to the substrate. A stiffener frame is mounted to the substrate and circumscribes the IC die. The stiffener frame has a plurality of connected walls that define an opening in the stiffener frame. The chip package also includes a lid having a bottom side facing a top surface of the IC die. The lid has at least a first guide and a second guide extending from the bottom side of the lid. The first guide can be disposed outward or inward of the stiffener frame. The first guide has a side facing an outer wall surface or an inner wall surface of the stiffener frame.

Another example of a chip package generally includes a substrate and an integrated circuit (“IC”) die mounted to the substrate, and a thermal interface material (TIM) disposed above the IC dies. A stiffener frame is mounted to the substrate and has a plurality of connected walls circumscribing the IC die. The chip package also includes a lid having a bottom side facing a top surface of the IC die. The lid has at least a first guide and a second guide extending from the bottom side of the lid. The first guide and the second guide are positioned to limit movement of the lid relative to the stiffener frame in two directions.

Yet another example of the present disclosure is a method of fabricating a chip package. The method generally includes forming a first guide and a second guide on a bottom surface of a lid; disposing the lid above a stiffener frame, wherein the first guide positioned inward or outward of a wall of the stiffener frame; and moving the first guide toward the wall of the stiffener frame.

These and other aspects may be understood with reference to the following detailed description.

### BRIEF DESCRIPTION OF THE DRAWINGS

So that the manner in which the above-recited features of the present disclosure can be understood in detail, a more particular description of the disclosure, briefly summarized above, may be had by reference to examples, some of which are illustrated in the appended drawings. It is to be noted, however, that the appended drawings illustrate only typical examples of this disclosure and are therefore not to be considered limiting of its scope, for the disclosure may admit to other equally effective examples.

FIG. 1A is a cross-sectional view of an exemplary integrated circuit (IC) package including one or more IC dies covered by a lid, in accordance with an example of the present disclosure.

FIG. 1B is a cross-sectional view of the IC package of FIG. 1A with a heat sink mounted to a printed circuit board, in accordance with an example of the present disclosure.

FIG. 2A is a bottom view of a lid of an exemplary IC package, illustrating two guides on the lid, in accordance with an example of the present disclosure.

FIG. 2B is a bottom view of a lid of another exemplary IC package, illustrating four guides on the lid, in accordance with an example of the present disclosure.

FIG. 2C is a bottom view of a lid of another exemplary IC package, illustrating four guides on the lid, in accordance with an example of the present disclosure.

FIG. 3A is a bottom view of an exemplary heat sink assembly equipped with a textured heat management device.

FIG. 3B is a side view of the heat sink assembly of FIG. 3A.

FIG. 4 illustrates an example heat sink assembly equipped with a textured heat management device implemented with an integrated vapor chamber or a heat pipe, in accordance with an example of the present disclosure.

FIG. 5 shows an exemplary embodiment of a lid attached to a printed circuit board.

FIG. 6A is a bottom view of another exemplary lid, according to embodiments of the present disclosure.

FIG. 6B is a cross-sectional view of the lid taken along line 6B-6B in FIG. 6A.

FIG. 7 is a flow diagram of example operations for fabricating an IC package with a lid having guides disposed on it bottom surface, in accordance with an example of the present disclosure.

To facilitate understanding, identical reference numerals have been used, where possible, to designate identical elements that are common to the figures. It is contemplated that elements of one example may be beneficially incorporated in other examples.

### DETAILED DESCRIPTION

Examples of the present disclosure provide apparatus and techniques for assembling a chip package using a lid having one or more guides to facilitate positioning the lid relative to the stiffener.

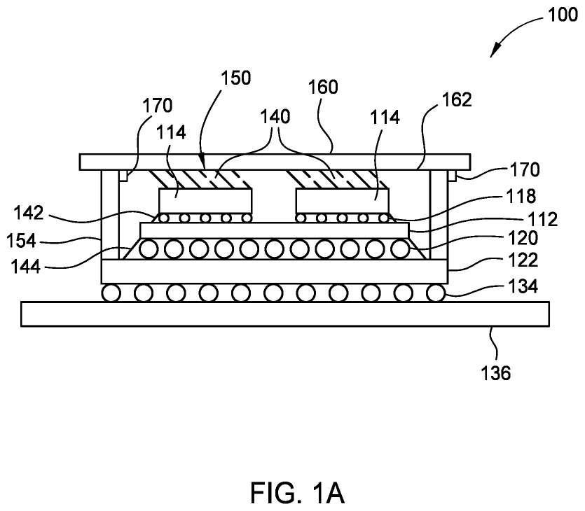

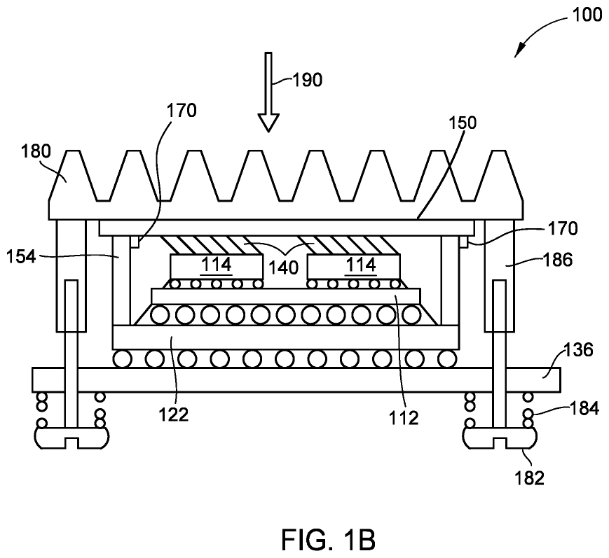

Turning now to FIG. 1A, an example integrated circuit (IC) package 100 is illustrated. The IC package 100 includes one or more IC dies 114 (also referred to as “chips”) connected optionally by an interposer 112 to a package substrate 122. Although two IC dies 114 are shown in FIG. 1A, the number of IC dies may range from one to as many as can be fit within the IC package 100.

The interposer 112 includes circuitry for electrically connecting the IC dies 114 to circuitry of the package substrate 122. The interposer 112 may be passive and contain interconnects (not shown) for connecting one of the IC dies 114 to another and/or through-silicon vias (TSVs) for connecting each of the IC dies to the package substrate 122. For other examples, the interposer 112 may be active and include transistors. Package bumps 120, also known as “controlled collapse chip connection (C4) bumps,” are utilized to provide an electrical connection between the circuitry of the interposer 112 and the circuitry of the package substrate 122. The package substrate 122 may be mounted and connected to a printed circuit board (PCB) 136, utilizing solder balls 134, wire bonding, or any other suitable technique. For some examples, an undermolding 144 may be utilized to fill the space not taken by the package bumps 120 between the package substrate 122 and the interposer 112, thereby providing structural rigidity to the IC package 100.

The IC dies 114 are mounted to one or more surfaces of the interposer 112, or alternatively in examples wherein an interposer is not utilized, to the package substrate 122. The IC dies 114 may be programmable logic devices (e.g., field programmable gate arrays (FPGAs)), memory devices, optical devices, processors, or other IC structures. Optical devices include photodetectors, lasers, optical sources, and the like. In the example depicted in FIG. 1A, the IC dies 114 are mounted to a top surface of the interposer 112 by a plurality of microbumps 118. The microbumps 118 electrically connect the circuitry of each IC die 114 to circuitry of the interposer 112. The circuitry of the interposer 112 connects the microbumps 118 to package bumps 120, and hence, connects selective circuitry of each IC die 114 to the package substrate 122, to enable communication of the IC dies 114 with the PCB 136, for example, after the IC package 100 is mounted within an electronic device (not shown). When the optional interposer 112 is not present, the microbumps 118 may connect selective circuitry of each IC die 114 to the package substrate 122 to enable communication of the IC dies 114 with the PCB 136. For some examples, an undermolding 142 may be utilized to fill the space not taken by the microbumps 118 between the IC dies 114 and interposer 112 to provide structural rigidity to the IC package 100.

The IC package 100 may additionally include a stiffener 154. The stiffener 154 may be coupled to the package substrate 122 and circumscribe the IC dies 114. The stiffener 154 can extend to peripheral edges of the package substrate 122 to provide mechanical support, which helps prevent the IC package 100 from bowing and warpage. The stiffener 154 may be a single-layer structure or a multi-layer structure. The stiffener 154 may be made of ceramic, metal, or other various inorganic materials, such as aluminum oxide (Al₂O₃), aluminum nitride (AlN), silicon nitride (SiN), silicon (Si), copper (Cu), aluminum (Al), diamond, and stainless steel, among other materials. The stiffener 154 can also be made of organic materials such as copper-clad laminate.

A lid 150 may be disposed over the IC dies 114. In some examples, the lid 150 may be fabricated from a plastic material or other suitable material. In other examples, particularly where it is desirable to utilize the lid 150 to receive and convey heat away from the IC dies 114, the lid 150 may be fabricated from a thermally conductive material, such as copper, nickel-plated copper, or aluminum, among other suitable materials. In some embodiments, the lid 150 may include diamonds, such as on a bottom surface of the lid 150. The lid 150 may have a thickness of between about 0.5 mm and about 3.0 mm, although other thicknesses may be utilized.

The lid 150 has a top surface 160 and a bottom surface 162. For some examples, the top surface 160 forms the exterior top surface of the IC package 100. The bottom surface 162 faces the IC dies 114. A heat sink (not shown in FIG. 1A) may optionally be mounted to the top surface 160 of the lid 150.

Generally, the lid 150 is disposed over the IC dies 114. A thermal interface material (TIM) 140 may be utilized to thermally and/or mechanically couple the lid 150 to the IC dies 114. The TIM 140 may be selected to provide a thermally conductive path between the lid 150 to the IC dies 114 so that heat generated by the IC dies 114 may be dissipated through the lid 150. The TIM 140 is generally a heat transfer material having a conductivity of at least about 0.1 W/m·K and is designed to displace the air that is present in the gaps between the lid 150 and the IC dies 114, thereby decreasing the thermal contact resistance. Examples of materials suitable for use as the TIM 140 include thermal grease, thermally conductive epoxy, phase-change materials (PCMs), conductive tapes, and silicone-coated fabrics among other suitable materials. The TIM 140 may be a soft or compliant adhesive to allow compensation between mismatched heights of neighboring IC dies 114 within the IC package 100. In one example, the TIM 140 may be a thermal gel or thermal epoxy, such as packaging component attach adhesives available from AI Technology, Inc., located in Princeton Junction, New Jersey. The PCM may be manufactured as a blend of hydrocarbon polymers to provide a material that has slight melting, but is mostly an amorphous solid that softens with temperature and does not suddenly change from a solid to a liquid state. One or more of these polymers may contain metal powder and/or ceramic fillers, which may be greater than 90% of the PCM by weight. The fillers may have a maximum particle size of 25 μm. In another example, the TIM 140 may be a phase-change material, such as Tpcm 780 or Tpcm 780SP available from Laird PLC of London, United Kingdom.

The lid 150 may also be disposed over the stiffener 154. In some implementations, the lid 150 may be bonded to the stiffener 154 by an adhesive (not shown), such as an epoxy.

In other implementations, the lid 150 is located relative to the stiffener 154 using one or more guides 170. The one or more guides 170 are attached to the lid 150 and used to facilitate positioning of the lid 150 above the stiffener 154. The guides 170 are configured to engage the sides of the stiffener 154 during the positioning of the lid 150 on the stiffener 154. The lid 150 and the stiffener 154 are mechanically decoupled, which allows the lid 150 to move freely (i.e., “float”) relative to the stiffener 154. In this manner, stresses between the lid 150 and the stiffener 154 are mechanically decoupled, resulting in less warpage and delamination of the various layers and components of the IC package 100.

In the example depicted in FIG. 1A, two guides 170 are attached to the lid 150. The guides 170 may be bonded, screwed in, force fit, or otherwise attached to the lid 150. The guides 170 may extend from the bottom surface 162 of the lid 150 and have a length sufficient to form an overlapping relationship with the stiffener 154. In some implementations, the guides 170 are an integral part of the lid 150. For example, the guides 170 may be formed by stamping the lid 150 to project the guides 170 from the bottom surface 162 of the lid 150. In another example, the guides 170 may be a projection formed during 3D printing of the lid 150. While two guides 170 are disclosed in this example, it is contemplated any suitable number of guides may be used to position the lid 150 above the stiffener 154, such as one, three, four, five, or more guides 170.

FIG. 1B is a cross-sectional view of the IC package 100 of FIG. 1A with a heat sink assembly 180 mounted to the printed circuit board 136. The heat sink assembly 180 is coupled to the printed circuit board 136 in a manner that secures the lid 150 to the stiffener 154. In some implementations, a fastener 182 may be threadingly engaged with posts 186 of the heat sink assembly 180 so that the heat sink assembly exerts a force on the lid 150 in a direction of the IC dies 114, as illustrated by arrow 190. Optionally, a spring 184 or other resilient object may be disposed between the fastener 182 and the printed circuit board 136 to provide force that the heat sink assembly 180 exerts on the lid 150. Advantageously, the force provided by the heat sink assembly 180 allows the lid 150 to maintain good thermal contact with the IC dies 114, while remaining floating on the stiffener 154.

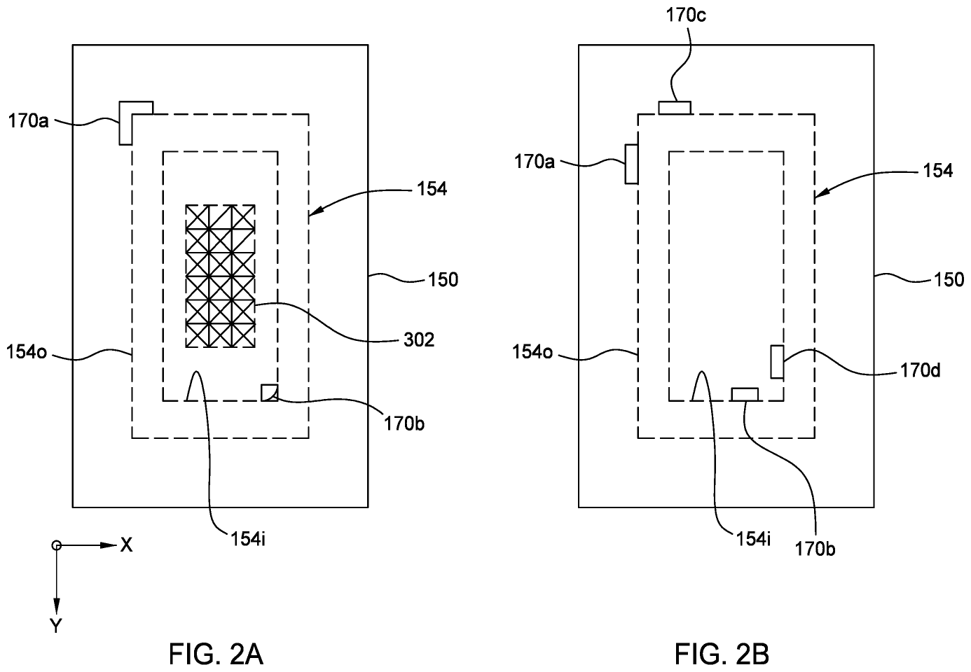

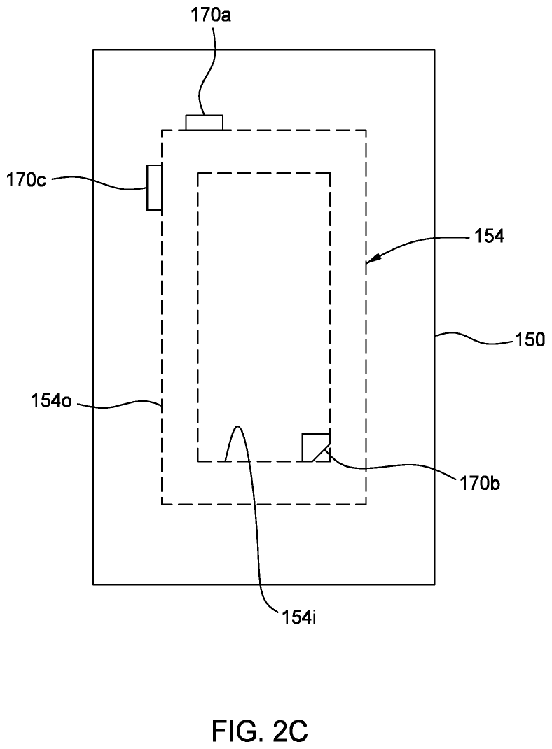

FIG. 2A is a bottom view of an exemplary embodiment of a lid 150 provided with a plurality of guides 170a, 170b. In some embodiments, the lid 150 may be the base plate of the heat sink assembly 180. The guides 170a, 170b extend from the bottom surface of the lid 150 to facilitate positioning of the lid 150 relative to the stiffener 154. FIG. 2A includes an exemplary stiffener 154 in dash lines to show the relative positions between the stiffener 154 and the guides 170a, 170b. The stiffener 154 is shown as a rectangular shaped frame formed by four connecting walls. An opening inside the frame is defined by the four connecting walls. The walls have an inner wall surface 154i and an outer wall surface 1540. In this example, the first guide 170a is positioned to engage two outer wall surfaces 1540 of the stiffener 154, and the second guide 170b is positioned to engage two inner wall surfaces 154i of the stiffener 154. In some examples, both of the first and second guides 170a, 170b are positioned to engage one or more the outer wall surfaces 1540 or both are positioned to engage one or more inner wall surfaces 154i. Advantageously, the guides 170a, 170b allow the lid 150 to be laterally located on the stiffener 154, while still allowing the lid 150 to float vertically relative to the stiffener 154.

The guides 170a, 170b may have any suitable shape for engaging a wall of the stiffener 154. Each of the guides 170a, 170b is configured to engage the inner wall surface 154i or the outer wall surface 1540 of one or two wall surfaces of the stiffener 154. As shown in FIG. 2A, the first guide 170a is configured to engage two adjacent outer wall surfaces 1540. In this example, the first guide 170a has two arms that form an “L” shape cross-sectional profile. Each of the arms are configured to engage an outer wall surface 1540. In some examples, the first guide 170a may have an arcuate shaped profile, such as a “C” shape cross-section, or any suitable shape having two contact points for engaging two outer wall surfaces 1540. The second guide 170b is configured to engage two adjacent inner wall surfaces 154i of two walls of the stiffener. In this example, the cross-sectional profile of the second guide 170b has two sides connected by an arcuate side, such as a quarter circle. The arcuate side faces two inner wall surfaces 154i. In another example, the second guide 170b may have an “L” shape cross-section, an arcuate shape cross-section, or any suitable cross-sectional shape having two contact points for engaging two inner wall surfaces 154i. Exemplary cross-sectional profiles include circle, polygon, or oval. The guides 170a, and 170b limit movement of the lid 150 relative to the stiffener 154 in the X and Y directions when the guides 170a, 170b contact the stiffener. In FIG. 2A, the first guide 170a and the second guide 170b are located at opposite corners from each other. In another example, the first guide 170a and the second guide 170b may be located at adjacent corners.

In another example, the first guide 170a and the second guide 170b are configured to engage a single wall surface of the stiffener 154. FIG. 2B shows the first guide 170a engaging one outer wall surface 1540 and the second guide 170b engaging one inner wall surface 154i. In this respect, the first guide 170a limits movement of the lid 150 in the X direction, and the second guide 170b limits movement of the lid 150 in the Y direction. Optionally, a third guide 170c is used to contact a second outer wall surface 1540. The third guide 170C will limit movement of the lid 150 in the Y direction. Alternatively, the third guide 170c or a fourth guide 170d can be positioned to contact a second inner wall surface 154i.

In yet another example, the first guide 170a is configured to engage one outer wall surface 1540, and the second guide 170b is configured to engage two inner wall surfaces 154i, as shown in FIG. 2C. In this example, the second guide 170b is a polygon having five sides, two of which is in contact with an inner wall surface 154i. Alternatively, the first guide 170a is configured to engage two outer wall surfaces 1540, and the second guide 170b is configured to engage one inner wall surface 154i. In some embodiments, a third guide 170c is used to contact a second outer wall surface 1540.

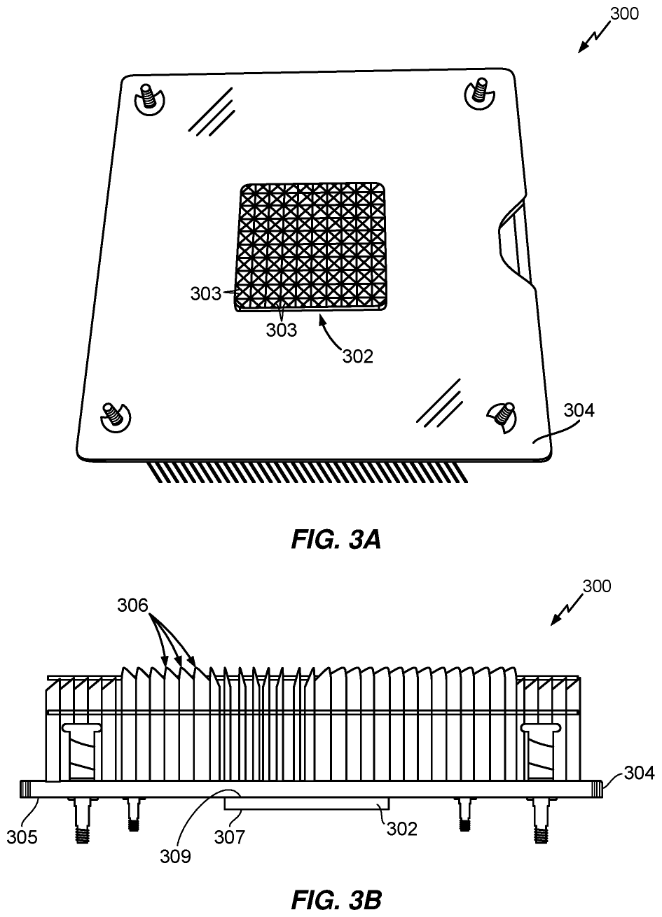

In some embodiments, the IC package 100 includes a heat management device with a textured surface having multiple grooves in an otherwise relatively flat surface. FIG. 3A is a bottom view of an exemplary textured heat management device 302 disposed adjacent a heat sink assembly 300. FIG. 3B is a side view of the heat sink assembly 300 of FIG. 3A. The heat sink assembly 300 may include a heat sink base plate 304, to which multiple heat sink fins 306 have been attached. The base plate 304 may be a lid (e.g., lid 150) of an IC package. FIG. 2A shows an exemplary textured heat management device 302 disposed on the bottom surface of the lid 150. The base plate 304/lid 150 may comprise any of various suitable metals, such as copper (Cu) or aluminum (Al). In some examples, the base plate 304/lid 150 may be comprise a vapor chamber and/or equipped with one or more heat pipes for heat spreading.

In some examples, the heat management device 302 may be a separate component that is attached to the base plate 304 (e.g., lid 150), whereas in other examples, the heat management device 302 may be an integral part of the base plate 304. Although the heat management device 302 is illustrated as being protruded from the lower surface 305 of the base plate 304 in the example of FIGS. 3A and 3B, for other examples, the heat management device 302 may be flush with or counter sunk in the lower surface 305 of the base plate 304. The upper surface 309 of the heat management device 302 may be plated with nickel (Ni) or another suitable material for preventing corrosion and/or for permitting the device to be soldered to the base plate 304.

The heat management device 302 may have a pattern of grooves 303 formed in the lower surface 307 of the heat management device 302. The heat management device 302 may comprise a mass (e.g., a plate or disc) of a suitable metal, such as Cu or Al. The grooves 303 may be formed in the metal mass via etching or any other suitable method. For some examples, the grooves 303 may be arranged in rows, in columns, as positive-sloping diagonals, as negative-sloping diagonals, or as a combination thereof, with respect to a particular orientation of the heat management device 302. In the example of FIG. 3A, the heat management device 302 has a first set of grooves arranged in rows, a second set of grooves arranged in columns perpendicular to and intersecting the rows at intersections, a third set of grooves arranged in positive-sloping diagonals intersecting the intersections between the rows and the columns, and a fourth set of grooves arranged in negative-sloping diagonals intersecting the same intersections. For some examples, the grooves 303 may have a depth on the order of 0.1 mm, and intersections of more than two grooves may have a depth on the order of 0.2 mm.

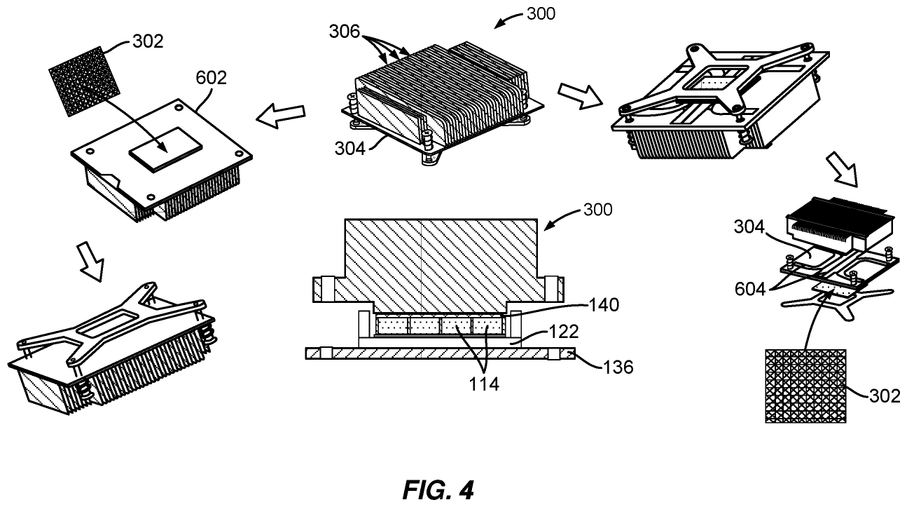

FIG. 4 illustrates an exemplary heat sink assembly 300 equipped with a heat management device 302 having a textured surface. The heat sink assembly 300 includes a plurality of fins 306 disposed on a base plate 304 (e.g., lid 150). In some examples, the heat sink assembly 300 is implemented with an integrated vapor chamber 602 as part of the base plate 304 or with heat pipes 604 embedded in a base plate 304. In some examples, the base plate 304 includes a chamber having inlet and outlet ports for circulating a heat transfer fluid, which chamber includes fins disposed therein.

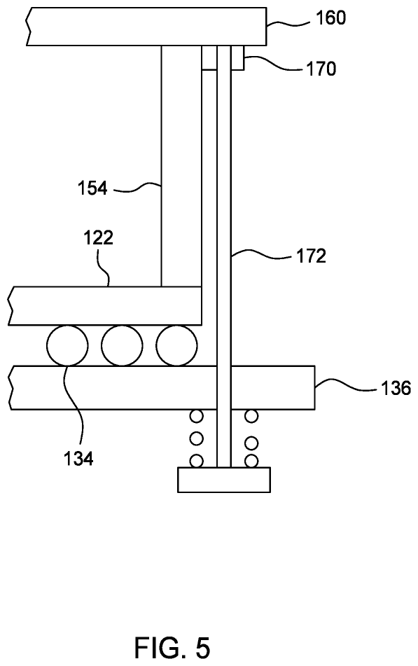

In some implementations, a fastener 172 may be engaged with a guide 170 of the lid 150 to urge the lid 150 in the direction of the IC dies 114. FIG. 5 shows the fastener 172 extending through the printed circuit board 136 and attached to a guide 170 positioned to engage the outer wall surface 1540 of the stiffener 154. In one example, the fastener 172 is a screw that threadedly connects to a hole in the guide 170. Optionally, a spring 174 or other resilient object may be disposed between the fastener 172 and the printed circuit board 136 to provide a biasing force on the lid 150. Advantageously, the force allows the lid 150 to maintain good thermal contact with the IC dies 114, while remaining floating on the stiffener 154.

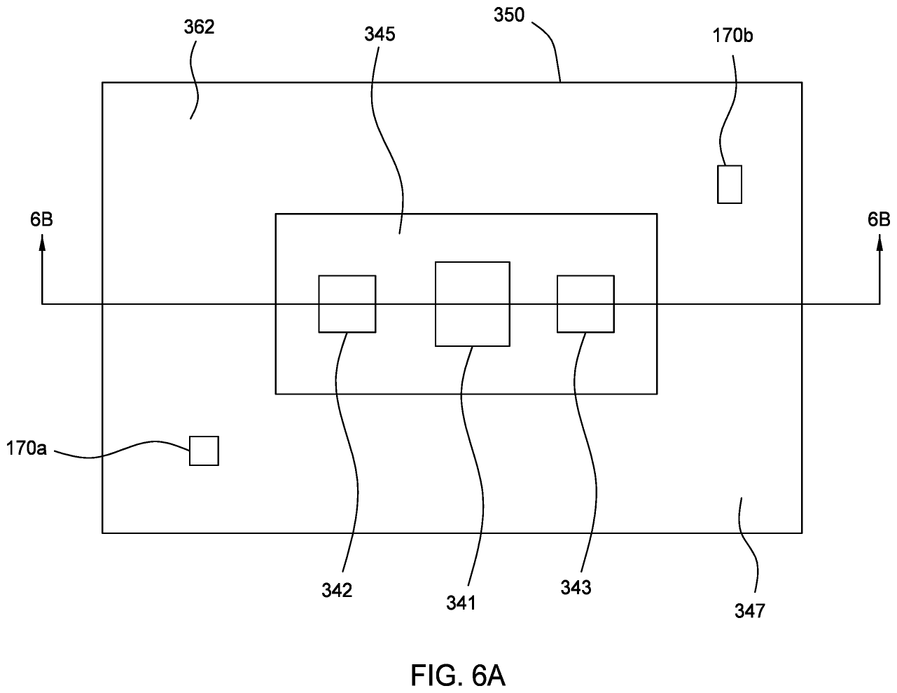

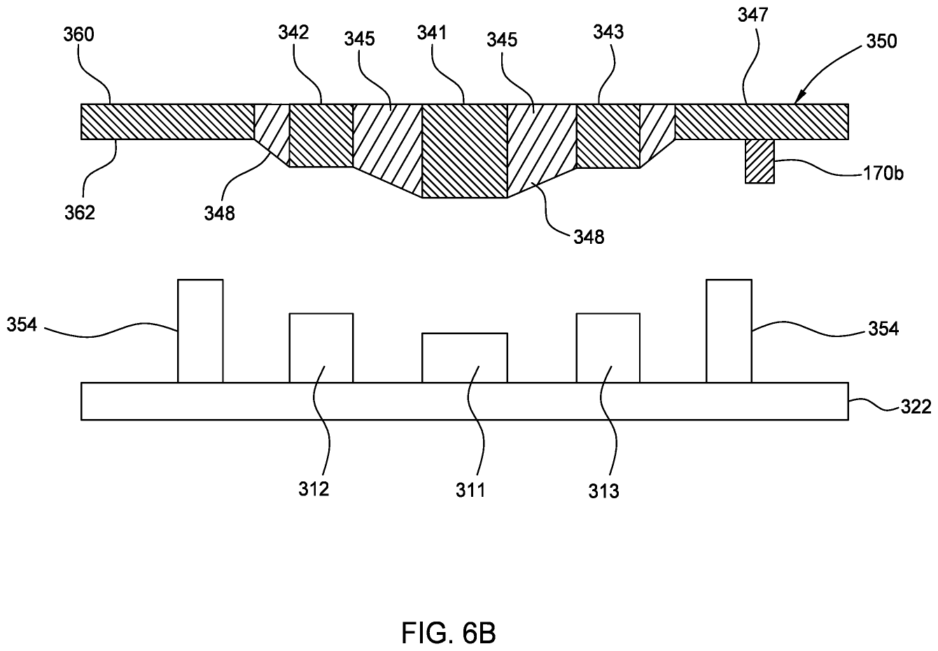

FIG. 6A is a bottom view of another exemplary lid 350, according to embodiments of the present disclosure. FIG. 6B is a cross-sectional view of the lid 350 taken along line 6B-6B. The lid 350 is suitable for use as the lid (e.g., lid 150) in any of the chip package embodiments described herein.

As shown in FIG. 6B, the lid 350 is positioned above IC dies 311, 312, 313, and the lid 350 is utilized to receive and convey heat away from the IC dies 311, 312, 313. For clarity, the IC dies 311, 312, 313 are shown disposed on a package substrate 322 only, such as the package substrate 122 shown in FIG. 1A. In this example, the IC die 311 has a height that is different than the height of IC dies 312, 313. In some examples, each of the IC dies 311, 312, 313 may have the same or different heights. A stiffener 354 is disposed around the IC dies 311, 312, 313 and on the package substrate 322.

The lid 350 has a top surface 360 and a bottom surface 362. For some examples, the top surface 360 forms the exterior top surface of an IC package, such as IC package 100. A heat sink (not shown in FIG. 6A-6B) may optionally be mounted to the top surface 360 of the lid 350. The bottom surface 362 faces the IC dies 311, 312, 313. The lid 350 may be fabricated from a thermally conductive material, such as copper, nickel-plated copper, or aluminum, among other suitable materials. In some embodiments, the lid 350 may include diamonds, such as on a bottom surface of the lid 350.

As shown in FIGS. 6A and 6B, the lid 350 includes a plurality of IC regions 341, 342, 343 surrounded by a transition region 345. In turn, the transition region 345 is surrounded by a perimeter region 347 of the lid 350. Each of the IC regions 341, 342, 343 is located above a corresponding IC die 311, 312, 313. The IC regions 341, 342, 343 protrude from the bottom surface 362 of the lid 350 and have thicknesses that are configured to accommodate the different heights of the corresponding IC die 311, 312, 313. In this example, the IC region 341 is thicker (e.g., extend lower) than the IC regions 342, 343 because the IC die 311 is lower in height than the IC dies 312, 313. In some examples, the bottom surface of the IC regions 341, 342, 343 has a generally planar shape. Although three IC regions are shown in this example, it is contemplated the lid 350 may have one, two, four, five, or more IC regions. Each of the IC regions may have the same or different thickness as compared to another IC region, depending on the height of the corresponding IC die. In some examples, the perimeter region 347 of the lid 350 may have a thickness from about 0.5 mm and to about 3.0 mm. At least one of the IC regions 341, 342, 343 may have a thickness greater than the thickness of the perimeter region 347.

The IC regions 341, 342, 343 are surrounded by the transition region 345. The transition region 345 is configured to accommodate the change in depth from one IC region 341, 342, 343 to another IC region 341, 342, 343 or to the perimeter region 347 of the lid 350. In this example, the transition region 345 forms a sloping surface 348 connecting one IC region to another IC region or the perimeter region 347. The sloping surface 348 may be linear, curved, or stepwise. The transition region 345 may be fabricated from a thermally conductive material, such as copper, nickel-plated copper, or aluminum, among other suitable materials. In some embodiments, the transition region 345 may have the same or different material as the IC regions 341, 342, 343. In some implementations, the transition region 345 is formed by molding.

A thermal interface material (e.g., TIM 140) may be utilized to thermally and/or mechanically couple the IC regions 341, 342, 343 of the lid 350 to the corresponding IC dies 311, 312, 313. The TIM may be selected to provide a thermally conductive path between the IC regions 341, 342, 343 to the IC dies 311, 312, 313 so that heat generated by the IC dies 311, 312, 313 may be dissipated through the lid 350.

The lid 350 may also be disposed over the stiffener 354. In some implementations, the lid 350 includes one or more guides (e.g., guides 170a, 170b) to facilitate positioning of the lid 350 above the stiffener 354. In some implementations, the lid 350 may include one or more pins for coupling with the stiffener 354. For example, the pins can be inserted into a hole of the stiffener 354 and allowed to move vertically in the hole. In some implementations, the lid 350 may be bonded to the stiffener 354 by an adhesive (not shown), such as an epoxy.

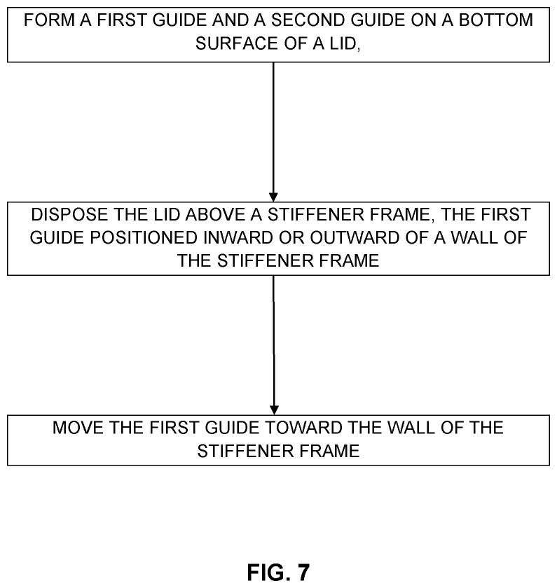

FIG. 7 is a flow diagram of example operations 600 for fabricating an IC package, in accordance with an example of the present disclosure. The operations 600 may begin, at block 612, by forming a first guide and a second guide (e.g., guides 170a, 170b) on a bottom surface of the lid (e.g., lid 150). At block 614, the lid is disposed above a stiffener (e.g., stiffener 154). The first guide is positioned inward or outward of a wall of the stiffener. At block 616, the lid is moved relative to the stiffener to move the first guide toward the wall of the stiffener.

Certain examples of the present disclosure provides a chip package including a substrate and an integrated circuit (“IC”) die mounted to the substrate. The chip package also includes a stiffener frame mounted to the substrate and circumscribing the IC die. The stiffener frame has a plurality of connected walls that define an opening in the stiffener frame. The chip package also includes a lid having a bottom side facing a top surface of the IC die. The lid has at least a first guide and a second guide extending from the bottom side of the lid. The first guide can be disposed outward or inward of the stiffener frame. The first guide has a side facing an outer wall surface or an inner wall surface of the stiffener frame.

According to some examples, the first guide is disposed outward of the stiffener frame, and the second guide is disposed inward of the stiffener frame.

According to some examples, the first guide and the second guide are disposed inward of the stiffener frame.

According to some examples, the first guide and the second guide are disposed outward of the stiffener frame.

According to some examples, at least one of the first guide and the second guide is configured to contact two adjacent wall surfaces of the stiffener frame.

According to some examples, the IC package includes a third guide extending from the bottom side of the lid, wherein the first guide, second guide, and the third guide are configured to contact different wall surfaces of the stiffener frame.

According to some examples, at least one of the guides has a cross-sectional profile that is a circle, polygon, or oval.

According to some examples, the IC package includes a spring loaded fastener connected to the first guide and biasing the lid towards the substrate.

According to some examples, the first guide and the second guide are movable with the lid and relative to the stiffener frame.

According to some examples, the lid includes diamonds disposed on a bottom surface.

According to some examples, the lid includes a vapor chamber.

According to some examples, the lid includes a top surface having fins.

According to some examples, the lid includes a chamber having inlet and outlet ports for circulating a heat transfer fluid.

According to some examples, the lid comprises a metal.

According to some examples, the lid includes a first IC region surrounded by a transition region and a perimeter region.

According to some examples, the first IC region has a thickness greater than a thickness of the transition region.

According to some examples, the lid further comprises a second IC region, wherein the second IC region has a thickness less than the thickness of the first IC region.

According to some examples, the transition region is positioned between the first IC region and the perimeter region.

According to some examples, the transition region has a sloping surface to accommodate the change in thickness from the first IC region to the transition region.

Certain examples of the present disclosure provides a chip package including a substrate and an integrated circuit (“IC”) die mounted to the substrate, and a thermal interface material (TIM) disposed above the IC dies. A stiffener frame is mounted to the substrate and has a plurality of connected walls circumscribing the IC die. The chip package also includes a lid having a bottom side facing a top surface of the IC die. The lid has at least a first guide and a second guide extending from the bottom side of the lid. The first guide and the second guide are positioned to limit movement of the lid relative to the stiffener frame in two directions.

According to some examples, the first guide and the second guide are movable with the lid and relative to the stiffener frame.

According to some examples, the first guide is disposed outward of the stiffener frame, and the second guide is disposed inward of the stiffener frame.

According to some examples, at least one of the first guide and the second guide is configured to contact two adjacent wall surfaces of the stiffener frame.

According to some examples, the IC package includes a third guide extending from the bottom side of the lid, wherein the first guide, second guide, and the third guide are configured to contact different wall surfaces of the stiffener frame.

Certain examples of the present disclosure provides a method of fabricating a chip package. The method generally includes forming a first guide and a second guide on a bottom surface of a lid; disposing the lid above a stiffener frame, wherein the first guide positioned inward or outward of a wall of the stiffener frame; and moving the first guide toward the wall of the stiffener frame.

According to some examples, the first guide is moved until the first guide contacts the wall.

According to some examples, the lid is moved until the second guide contacts a second wall of the stiffener frame.

According to some examples, the method includes attaching a fastener to the first guide to apply a biasing force on the lid.

As used herein (including the claims that follow), a phrase referring to “at least one of” a list of items refers to any combination of those items, including single members. As an example, “at least one of: x, y, and z” is intended to cover: x, y, z, x-y, x-z, y-z, x-y-z, and any combination thereof (e.g., x-y-y and x-x-y-z).

While the foregoing is directed to examples of the present disclosure, other and further examples of the disclosure may be devised without departing from the basic scope thereof, and the scope thereof is determined by the claims that follow.

What is claimed is:

1. A chip package, comprising:
a substrate;
an integrated circuit (“IC”) die mounted to the substrate;
a stiffener frame mounted to the substrate and circumscribing the IC die, the stiffener frame having a plurality of connected walls defining an opening in the stiffener frame; and
a lid having a bottom side facing a top surface of the IC die, the lid having at least a first guide and a second guide extending from the bottom side of the lid, the first guide disposed outward or inward of the stiffener frame, the first guide having a side facing one of an outer wall surface or an inner wall surface of the stiffener frame.

2. The chip package of claim 1, wherein the first guide is disposed outward of the stiffener frame, and the second guide is disposed inward of the stiffener frame.

3. The chip package of claim 1, wherein the first guide and the second guide are disposed inward of the stiffener frame.

4. The chip package of claim 1, wherein the first guide and the second guide are disposed outward of the stiffener frame.

5. The chip package of claim 1, wherein at least one of the first guide and the second guide is configured to contact two adjacent wall surfaces of the stiffener frame.

6. The chip package of claim 1, further comprising a third guide extending from the bottom side of the lid, wherein the first guide, second guide, and the third guide are configured to contact different wall surfaces of the stiffener frame.

7. The chip package of claim 1, wherein at least one of the first guide and the second guide has a cross-sectional profile that is a circle, polygon, or oval.

8. The chip package of claim 1, further comprising a spring loaded fastener connected to the first guide and biasing the lid towards the substrate.

9. The chip package of claim 1, wherein the first guide and the second guide are movable with the lid and relative to the stiffener frame.

10. The chip package of claim 1, wherein the lid includes diamonds disposed on a bottom surface.

11. The chip package of claim 1, wherein the lid includes a vapor chamber, a top surface having fins, a chamber having inlet and outlet ports for circulating a heat transfer fluid, or combinations thereof.

12. The chip package of claim 1, wherein the lid includes a first IC region surrounded by a transition region and a perimeter region.

13. The chip package of claim 12, wherein the transition region is positioned between the first IC region and the perimeter region.

14. The chip package of claim 13, wherein the transition region has a sloping surface to accommodate a change in thickness from the first IC region to the transition region.

15. A chip package, comprising:
a substrate;
an integrated circuit (“IC”) die mounted to the substrate;
a thermal interface material (TIM) disposed above the IC dies;
a stiffener frame mounted to the substrate and having a plurality of connected walls circumscribing the IC die; and
a lid having a bottom side facing a top surface of the IC die, the lid having at least a first guide and a second guide extending from the bottom side of the lid, the first guide and the second guide positioned to limit movement of the lid relative to the stiffener frame in two directions.

16. The chip package of claim 15, wherein the first guide and the second guide are movable with the lid and relative to the stiffener frame.

17. The chip package of claim 15, wherein the first guide is disposed outward of the stiffener frame, and the second guide is disposed inward of the stiffener frame.

18. The chip package of claim 15, wherein at least one of the first guide and the second guide is configured to contact two adjacent wall surfaces of the stiffener frame.

19. The chip package of claim 15, further comprising a third guide extending from the bottom side of the lid, wherein the first guide, second guide, and the third guide are configured to contact different wall surfaces of the stiffener frame.

20. A method of fabricating a chip package, comprising:
forming a first guide and a second guide on a bottom surface of a lid;
disposing the lid above a stiffener frame, the first guide positioned inward or outward of a wall of the stiffener frame; and
moving the first guide toward the wall of the stiffener frame.

21. The method of claim 20, wherein moving the first guide toward the wall of the stiffener frame comprises moving the first guide until the first guide contacts the wall.

22. The method of claim 21, further comprising moving the lid until the second guide contacts a second wall of the stiffener frame.

23. The method of claim 20, further comprising attaching a fastener to the first guide to apply a biasing force on the lid.

24. The chip package of claim 12, wherein the first IC region has thickness greater than a thickness of the transition region.

25. The chip package of claim 12, wherein the lid further comprises a second IC region, wherein the second IC region has a thickness less than the thickness of the first IC region.
